(19) United States
(12) Patent Application Publication
(10) Pub. No.: US 2023/0352581 A1
(43) Pub. Date: Nov. 2, 2023

(54) THREE-DIMENSIONAL DEVICE AND METHOD OF FORMING THE SAME

(71) Applicant: Tokyo Electron Limited, Tokyo (JP)

(72) Inventors: H. Jim FULFORD, Marianna, FL (US); Mark I. GARDNER, Cedar Creek, TX (US); Partha MUKHOPADHYAY, Oviedo, FL (US)

(73) Assignee: Tokyo Electron Limited, Tokyo (JP)

(21) Appl. No.: 17/730,824

(22) Filed: Apr. 27, 2022

(51) Int. Cl. H01L 29/78; H01L 29/22; H01L 29/24; H01L 27/092; H01L 29/417; H01L 29/66; H01L 29/40

(52) U.S. Cl. CPC H01L 29/7827; H01L 29/22; H01L 29/24; H01L 27/092; H01L 29/41741; H01L 29/66666; H01L 29/401

(57) ABSTRACT

According to an aspect of the disclosure, a semiconductor device is provided. The semiconductor device includes a first bottom contact positioned in a dielectric layer over a substrate, and a first channel structure extending from and in contact with the first bottom contact in a vertical direction perpendicular to the substrate. The first channel structure includes a bottom portion over the first bottom contact, a middle portion over the bottom portion, and a top portion over the middle portion. The semiconductor device includes a first gate structure positioned around the middle portion of the first channel structure, and a first top contact positioned over and in contact with the top portion of the first channel structure.

### FIELD OF THE INVENTION

The disclosure relates to microelectronic devices including semiconductor devices, transistors, and integrated circuits, including methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

3D integration, i.e., the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

Techniques herein include methods and devices for 3D fabrication of semiconductor devices. Specifically, logic circuits and memory circuits can be built based on vertical field effect transistor (VFET) structures with self-aliened processing. In the disclosure, low Dt process can be integrated as standalone devices or 3D sequential circuit builds. A deposited channel region (e.g., conductive oxides) can be utilized as 3D building block stacks for N devices tall. The deposited channel region may have metal layers beneath the device to enable source and drain connections. Channel geometries made of conductive oxides can be deposited and etched to form a 3D network of vertical nano sheets. Thus, no epitaxial silicon is required during the process. In the disclosure, complemental field effect transistor (CFET) and side by side CMOS devices can be implemented based on the disclosed VFET structures. Polarity of the VFET stacks can be varied as p-type or n-type. In addition, gate all around (GAA), different High-k, gate metal as well as source/drain metal can be used as options. Further, buried power rail and meal routing between VFET stacks can be applied. In the disclosure, two different flows can be implemented to create VFET stacks. Very low off state leakage and robust transistor properties can be obtained with this conductive oxide stack design.

In a first manufacturing flow of the disclosure, a metal first layer design for fabricating transistors with conductive oxide layers is provided. Pre-aligned mask can be applied for easy etching trench to fabricate device. Accordingly, alignment offset of 3 different masks has no effect or impact on device performance.

In a second manufacturing flow, a number of stacks of conductive oxide nanosheet can be provided. Polarity of the stack can be varied as p-type or n-type. Different High-k, gate metal as well as source/drain metal can be used as options.

Of course, an order of the manufacturing steps disclosed herein is presented for clarity sake. In general, these manufacturing steps can be performed in any suitable order. Additionally, although each of the different features, techniques, configurations, etc. herein may be discussed in different places of the present disclosure, it should be noted that each of the concepts can be executed independently from each other or in combination with each other. Accordingly, the present disclosure can be embodied and viewed in many different ways.

It should be noted that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

According to an aspect of the disclosure, a semiconductor device is provided. The semiconductor device can include a first bottom contact positioned in a dielectric layer over a substrate, and a first channel structure extending from and in contact with the first bottom contact in a vertical direction perpendicular to the substrate. The first channel structure can include a bottom portion over the first bottom contact, a middle portion over the bottom portion, and a top portion over the middle portion. The semiconductor device can include a first gate structure positioned around the middle portion of the first channel structure, and a first top contact positioned over and in contact with the top portion of the first channel structure.

In some embodiments, the first channel structure can have one of a circular pillar-shape, a square pillar-shape, an oval pillar-shape, and a rectangular pillar-shape.

In some embodiments, the bottom portion of the first channel structure can have a height in a range from 5 nm to 30 nm. The top portion of the first channel structure can have a height in a range from 5 nm to 30 nm, and the first channel structure can have a height in a range from 15 nm to 90 nm.

The first gate structure can further include a first gate dielectric layer around the middle portion of the first channel structure, and a first gate electrode around the first gate dielectric layer.

The semiconductor device can include an interconnect structure positioned over the first top contact, a second bottom contact positioned over the interconnect structure, and a second channel structure extending from and in contact with the second bottom contact in the vertical direction. The second channel structure can include a bottom portion over the second bottom contact, a middle portion over the bottom portion, and a top portion over the middle portion. The semiconductor can also include a second gate structure positioned around the middle portion of the second channel structure, and a second top contact positioned over and in contact with the top portion of the second channel structure.

In some embodiments, the second gate structure can further include a second gate dielectric layer around the middle portion of the second channel structure, and a second gate electrode around the second gate dielectric layer.

In some embodiments, the first channel structure and the second channel structure can be made of a conductive oxide. The conductive oxide can include one of In₂O₃, SnO₂, InGaZnO, ZnO, and SnO.

In an embodiment, the first channel structure can be made of a n-type conductive oxide and the second channel structure can be made of a p-type conductive oxide.

In another embodiment, the first channel structure can be made of a p-type conductive oxide and the second channel structure can be made of a n-type conductive oxide.

The semiconductor device can further include a third bottom contact positioned in the dielectric layer over the substrate, and a third channel structure extending from and in contact with the third bottom contact. The third channel structure can include a bottom portion over the third bottom contact, a middle portion over the bottom portion, and a top portion over the middle portion. The semiconductor device can include a third gate structure positioned around the middle portion of the third channel structure, and a third top contact positioned over and in contact with the top portion of the third channel structure. The third channel structure and the first channel structure can be arranged side by side over the substrate in a horizontal direction parallel to the substrate. The first top contact and the third top contact can be coupled to each other through a metal layer that is parallel to a main surface of the substrate.

According to another aspect of the disclosure, a method of forming a semiconductor device is provided. In the method, a first bottom contact can be formed in a dielectric layer over a substrate, and a first channel structure can be formed to extend from and in contact with the first bottom contact in a vertical direction perpendicular to the substrate. The first channel structure can include a bottom portion over the first bottom contact, a middle portion over the bottom portion, and a top portion over the middle portion. Further, a first gate structure can be formed around the middle portion of the first channel structure, and a first top contact can be formed over and in contact with the top portion of the first channel structure.

To form the first channel structure, an insulating layer can be formed over the dielectric layer. An opening can be formed in the insulating layer to uncover the first bottom contact. A conduct oxide can be formed in the opening to form the first channel structure.

To form the first gate structure, the insulating layer can be recessed such that the middle portion and the top portion of the first channel structure can be uncovered. A first gate dielectric layer can be formed around the middle portion and the top portion of the first channel structure. A first gate electrode can be formed around the first gate dielectric layer. The first gate dielectric layer and the first gate electrode can further be recessed such that the top portion of the first channel structure is uncovered.

To form the first top contact, an isolation layer can be formed over the insulating layer such that a top surface of the isolation layer is above a top surface of the first channel structure. An opening can be formed in the isolation layer to uncover the top surface of the first channel structure, and a conductive material can subsequently be deposited in the opening to form the first top contact.

In the method, an interconnect structure can be formed over the first top contact. A second bottom contact can be formed over the interconnect structure. A second channel structure can be formed to extend from and in contact with the second bottom contact. The second channel structure can include a bottom portion over the second bottom contact, a middle portion over the bottom portion, and a top portion over the middle portion. A second gate structure can be formed around the middle portion of the second channel structure. A second top contact can be formed over and in contact with the top portion of the second channel structure.

To form the second gate structure, a second gate dielectric layer can be formed around the middle portion of the second channel structure, and a second gate electrode can be formed around the second gate dielectric layer.

In the method, a third bottom contact can be formed in the dielectric layer. A third channel structure can be formed to extend from and in contact with the third bottom contact in the vertical direction. The third channel structure can include a bottom portion over the third bottom contact, a middle portion over the bottom portion, and a top portion over the middle portion. A third gate structure can be formed around the middle portion of the third channel structure. A third top contact can be formed over and in contact with the top portion of the third channel structure. The third channel structure and the first channel structure can be arranged side by side over the substrate in a horizontal direction parallel to the substrate. The first top contact and the third top contact can be coupled to each other through a metal layer that is parallel to a main surface of the substrate.

In some embodiments, the first channel structure and the second channel structure can be made of a conductive oxide. The conductive oxide can includes one of In₂O₃, SnO₂, InGaZnO, ZnO, and SnO.

In some embodiments, the first channel structure can be made of one of a n-type conductive oxide and a p-type conductive oxide, and the second channel structure can be made of one of a n-type conductive oxide and a p-type conductive oxide.

In some embodiments, the bottom portion of the first channel structure can have a height in a range from 5 nm to 30 nm, the top portion of the first channel structure can have a height in a range from 5 nm to 30 nm, and the first channel structure can have a height in a range from 15 nm to 90 nm.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top down view of a first semiconductor device, in accordance with some embodiments.

FIG. 1B is a cross-sectional view of the first semiconductor device, in accordance with some embodiments.

FIG. 1C is a perspective view of the first semiconductor device, in accordance with some embodiments.

FIGS. 2A, 2B, 3A, 3B, 4A, 4B, 5A, 5B, 6A, 6B, 7A, 7B, 8A, 8B, 9A, 9B, 10A, and 10B are top down views and cross-sectional views of various intermediate steps in a manufacturing flow to fabricate the first semiconductor device, in accordance with some embodiments.

FIG. 11A is a perspective view of a second semiconductor device, in accordance with some embodiments.

FIG. 11B is a top down view of the second semiconductor device, in accordance with some embodiments.

FIG. 11C is a cross-sectional view of the second semiconductor device, in accordance with some embodiments.

FIGS. 12A, 12B, 13A, 13B, 14A, 14B, 15A, 15B, 16A, 16B, 17A, 17B, 18A, 18B, 19A, 19B, 20A, and 20B are top down views and cross-sectional views of various intermediate steps in a manufacturing flow to fabricate the second semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the apparatus in use or operation in addition to the orientation depicted in the figures. The apparatus may be otherwise oriented (rotated 90 degrees or at other orientations) and the spatially relative descriptors used herein may likewise be interpreted accordingly.

Reference throughout the specification to “one embodiment” or “an embodiment” means that a particular feature, structure, material, or characteristic described in connection with the embodiment is included in at least one embodiment, but do not denote that they are present in every embodiment. Thus, the appearances of the phrases “in one embodiment” in various places through the specification are not necessarily referring to the same embodiment. Furthermore, the particular features, structures, materials, or characteristics may be combined in any suitable manner in one or more embodiments.

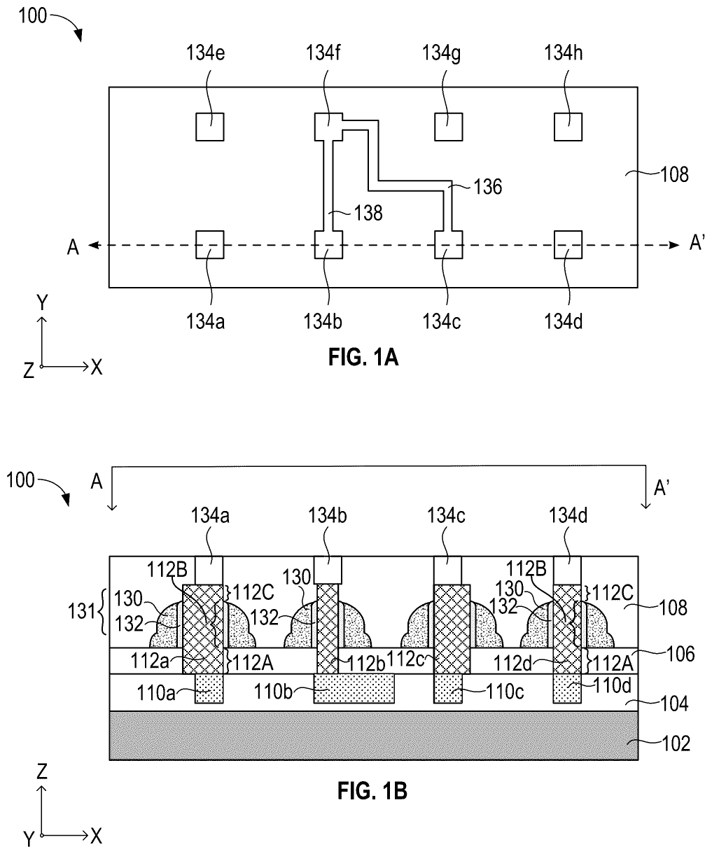

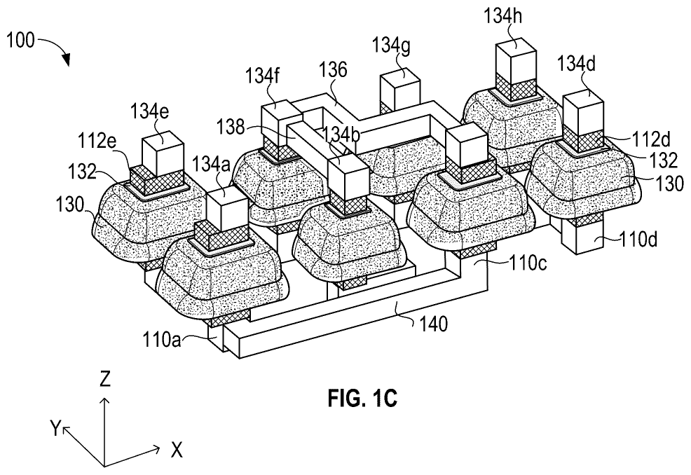

FIG. 1A is a top down view of a semiconductor device (or device 100). The device 100 can include a plurality of top contacts 134a-134h that are positioned in an isolation layer 108. In some embodiments, one or more of the top contacts 134a-134h can be connected to each other through metal layers. For example, the top contact 134b and the top contact 134f can be connected to each other through a metal line (or metal layer) 138, and the top contact 134c and the top contact 134f can be connected to each other through a metal line (or metal layer) 136. In some embodiments, the top contacts 134a-134h and the metal lines 136-138 can be made of a conductive material, such as Co, Ru, W, Al, and Cu.

FIG. 1B is a cross-sectional view of the device 100, which can be obtained from a same plane as a vertical plane along line A-A′ in FIG. 1A. As shown in FIG. 1, the device 100 can include a plurality of bottom contact 110a-110d positioned in a dielectric layer 104 over a substrate 102, and a plurality of channel structure 112a-112d extending from and in contact with the bottom contacts 110a-110d in a vertical direction (e.g., Z direction) perpendicular to the substrate 102. For example, the channel structure 112a is positioned over the bottom contact 110a, and the channel structure 112b is positioned over the bottom contact 110b. Each of the channel structures 112a-112d can include a bottom portion 112A over a respective bottom contact, a middle portion 112B over the bottom portion 112A, and a top portion 112C over the middle portion 112B. The bottom portions 112A of the channel structures 112a-112d can be arranged in an insulating layer 106 that is positioned over the dielectric layer 104.

The device 100 can include a plurality of gate structures 131 positioned around the middle portions 112B of the channel structure 112a-112d, and a plurality of top contacts 134a-134d positioned over and in contact with the top portions 112C of the channel structures 112a-112d. For example, the top contact 134a is positioned over the top portion of the channel structure 112a. Each of the gate structures 131 can further include a gate dielectric layer 132 around a respective middle portion of a channel structure, and a gate electrode 130 around the gate dielectric layer 132.

Still referring to FIG. 1B, the middle portions 112B, the top portions 112C, the gate structures 131, and the top contacts 134a-134b can be positioned in the isolation layer 108.

In some embodiments, the channel structures 112a-112d can have one of a circular pillar-shape, a square pillar-shape, an oval pillar-shape, and a rectangular pillar-shape.

In some embodiments, the bottom portions 112A of the channel structures 112a-112d can have a height in a range from 5 nm to 30 nm. The top portions 112C of the channel structure 112a-112d can have a height in a range from 5 nm to 30 nm, and the channel structures 112a-112d can have a height in a range from 15 nm to 90 nm.

In the device 100, the bottom portions 112A of the channel structures 112a-112d can function as first source/drain (S/D) structures, the middle portions 112B of the channel structures 112a-112d can function as channel layers, and the top portions 112C of the channel structures 112a-112d can function as second S/D structures. Accordingly, the channel structures 112a-112d and the gate structures 131 can form a plurality of vertical field effect transistors (VFETs). The bottom contacts 110a-110d can accordingly function as interconnects to the first S/D structures of the VFETs, and the top contacts 134a can function as interconnects to the second S/D structures of the VFETs.

In some embodiments, the gate dielectric layers 132 can include SiO₂, HfO₂, ZrO₂, HfSiNO₂, ZrSiNO₂, Y₃O₄, Si₃N₄, Al₂O₃, the like, or a combination thereof. In some embodiments, the channel structures 112a-112d can be made of a n-type conductive oxide, such as In₂O₃, SnO₂, InGaZnO, or ZnO. The gate electrodes 130 can include a work function layer (e.g., TiC, AlTiC, AlTiO), a liner (e.g., TiN), and a filler (e.g., W or Ru). Accordingly, the VFETs can be n-type transistors. In some embodiments, the channel structures 112a-112d can be made of a p-type conductive oxide, such as SnO. The gate electrodes 130 can include a work function layer (e.g., TiON, TiC, AlTiN, AlTiC, AlTiO), a liner (e.g., TiN and/or TaN), and a filler (e.g., W or Ru). Accordingly, the VFETs can be p-type transistors.

The bottom contacts 110a-110d can include conductive material, such as Co, Ru, W, Al, and Cu. The dielectric layer 104, the insulating layer 106, and the isolation layer 108 can be made of a dielectric material, such as SiO, SiN, SiON, SiC, SiOC, SiCN, SiOCN, the like, or a combination thereof.

FIG. 1C is a perspective view of the device 100. As shown in FIG. 1C, one or more bottom contacts can also be connected to each other through metal lines. For example, the bottom contact 110a can further be connected to the bottom contact 110c through a metal line (or metal layer) 140. Based on the connection between the bottom contacts and the connection between the top contacts, the VFETs can be connected to each other so as to form a functional circuit.

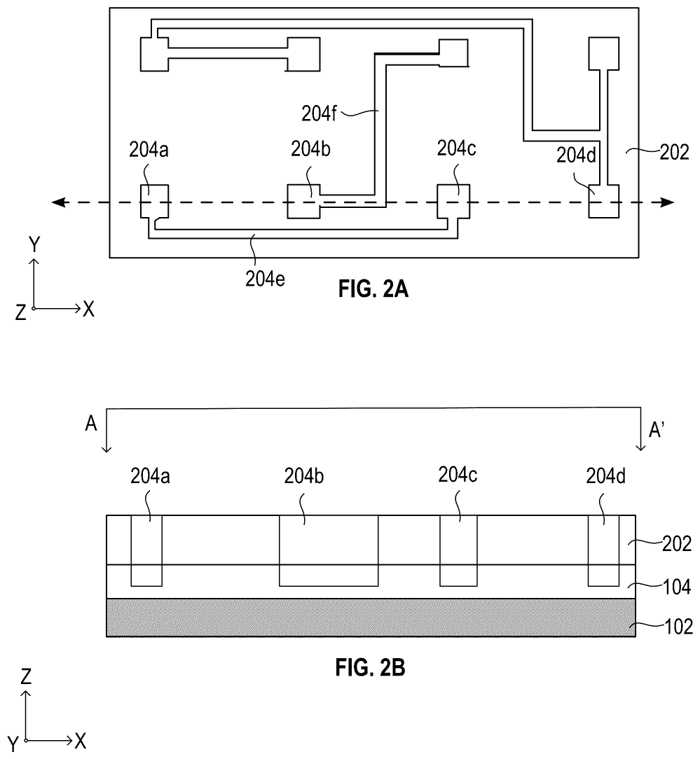

FIGS. 2A, 2B, 3A, 3B, 4A, 4B, 5A, 5B, 6A, 6B, 7A, 7B, 8A, 8B, 9A, 9B, 10A, and 10B are top down views and cross-sectional views of various intermediate steps in a manufacturing flow to fabricate the device 100, in accordance with some embodiments. As shown in FIG. 2A, a plurality of contact openings (e.g., 204a-204d) and trench openings (e.g., 204e-240f) can be formed based on an etching mask 202. FIG. 2B is a cross-sectional view, which can be obtained from a same plane as a vertical plane along line A-A′ in FIG. 2A. As shown in FIG. 2B, a dielectric layer 104 can be formed over the substrate 102, and the mask 202 can be formed over the dielectric layer 104. Patterns can be formed in the mask 202 based on a photolithography process, and an etching process can subsequently transfer the patterns into the dielectric layer 104 to form the contact openings and trench openings.

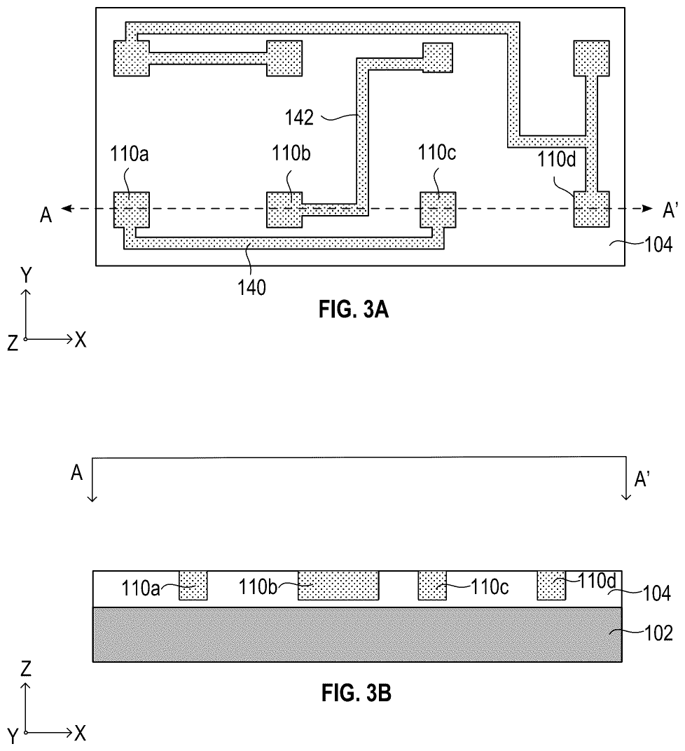

In FIGS. 3A and 3B, a plurality of bottom contacts (e.g., 110a-110d) and metal lines (e.g., 140 and 142) can be formed based on the contact openings and trench openings. FIG. 3A is a top down view and FIG. 3B is a cross-sectional view obtained from a same plane as a vertical plane along line A-A′ in FIG. 3A. In order to form the bottom contacts and metal lines, the mask 202 can be removed by an etching process or a plasma ashing process. A conductive material, such as W, Co, or Ru, can be deposited into the openings and trench openings. Any excessive conductive material over the dielectric layer 104 can be removed by a chemical mechanical planarization (CMP) process or an etching back process. The conductive material remaining in the openings and the trench openings can become the bottom contacts (e.g., 110a-110d) and metal lines (e.g., 140 and 142).

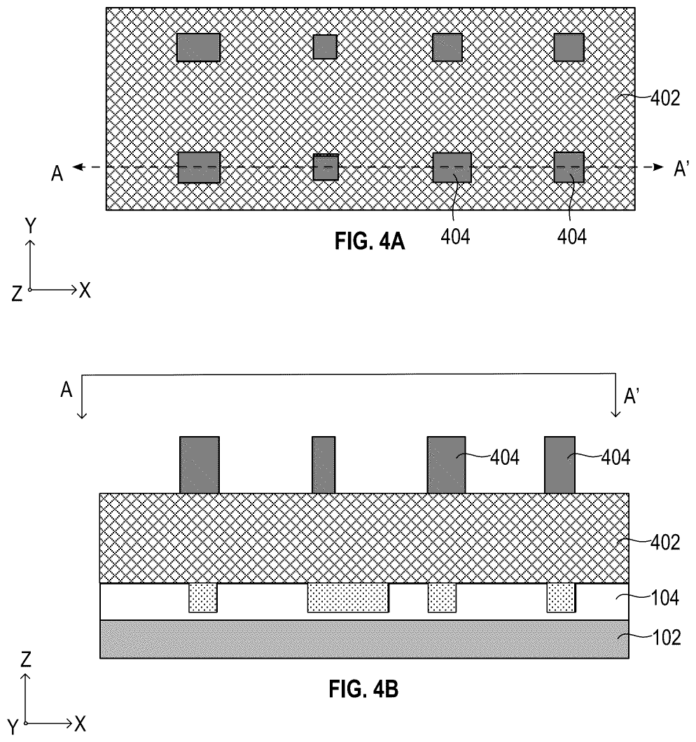

In FIGS. 4A and 4B, a conductive oxide layer 402 can be formed over the dielectric layer. Further, a patterned mask layer 404 can be formed over the conductive oxide layer 402. The conductive oxide layer 402 can be formed by any suitable deposition processes, such as a chemical vapor deposition (CVD), a physical vapor deposition (PVD), an atomic layer deposition (ALD), an e-beam evaporation, a sputtering, a diffusion, or any combination thereof. The patterned mask layer 404 can be formed based on a photolithography process. The conductive oxide layer 402 can include one of In₂O₃, SnO₂, InGaZnO, ZnO, and SnO.

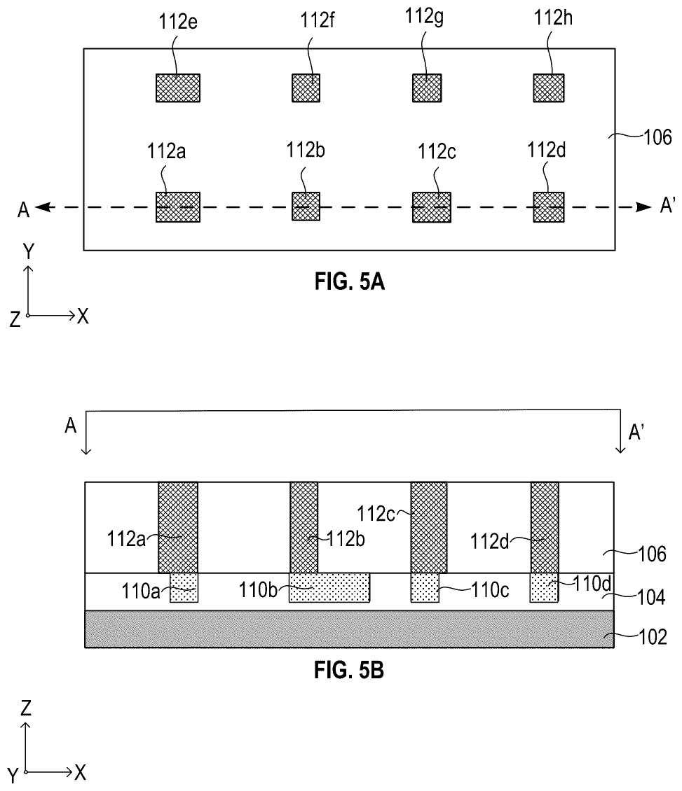

In FIGS. 5A and 5B, an etching process can be applied to etch the conductive oxide layer 402. Portions of the conductive oxide layer 402 that are not covered by the patterned mask layer 404 are removed, and portions of the conductive oxide layer 402 that are covered by the patterned mask layer 404 can still remain. The remaining conductive oxide layer 402 can become channel structures 112a-112h. The channel structures 112a-112h can be aligned with the bottom contacts 110a-110h such that the channel structures 112a-112h can be positioned over and in contact with the bottom contacts 110a-110h. Further, an insulating layer 106 can be formed to cover the channel structures 112a-112h.

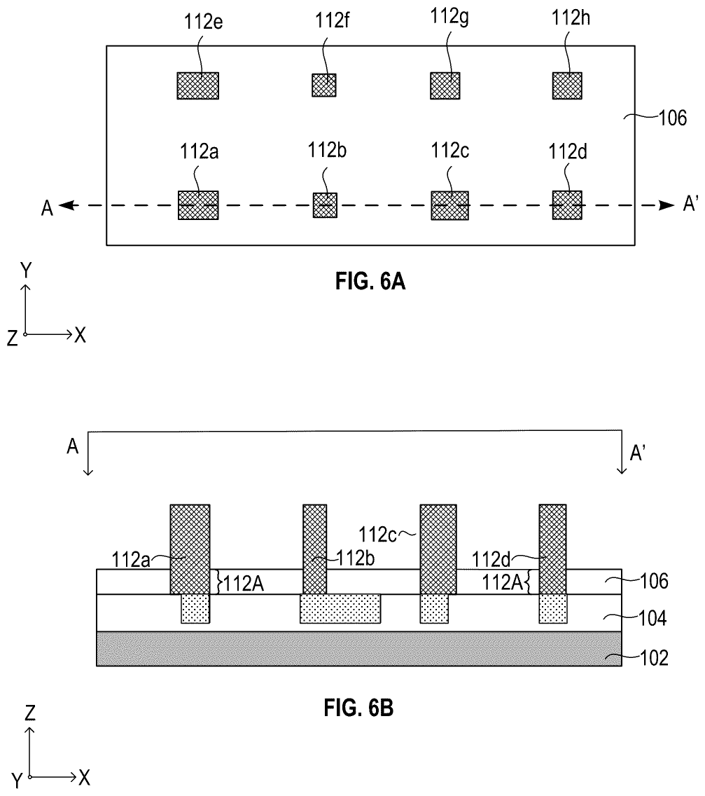

In FIGS. 6A and 6B, the insulating layer 106 can be recessed through an etching process. In some embodiments, the remaining insulating layer 106 can have a height equal to one third or one fourth of a height of the channel structures 112a-112h. The portions of the channel structures 112a-112h that are positioned in the insulating layer 106 can be bottom portions 112A of the channel structures 112a-112h. In some embodiments, the height of the channel structures 112a-112h can be in a range from 15 nm to 90 nm. The bottom portions 112A of the channel structures 112a-112h can be in a range from 5 nm to 30 nm.

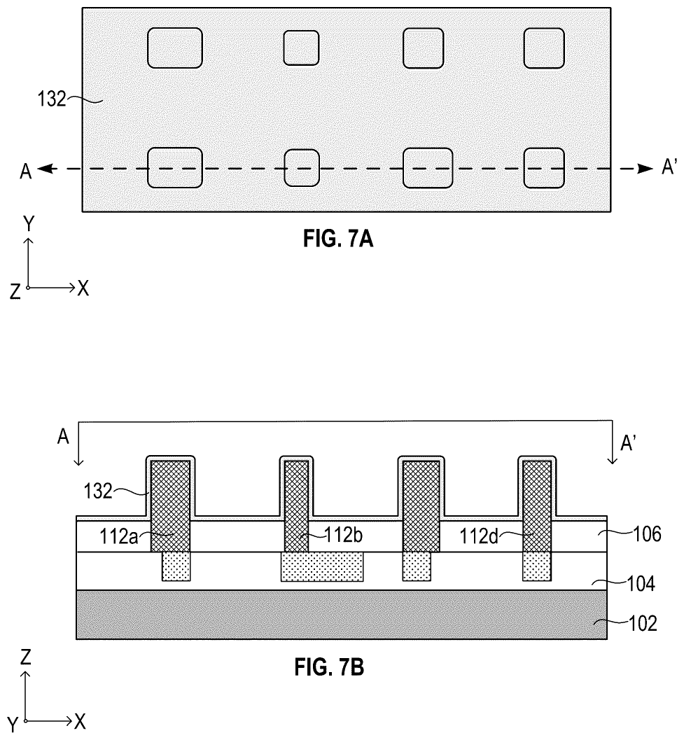

In FIGS. 7A and 7B, a gate dielectric layer 132 can be formed to cover the portions of the channel structures 112a-112h that are protruding from the insulating layer 106. The gate dielectric layer 132 can include SiO₂, HfO₂, ZrO₂, HfSiNO₂, ZrSiNO₂, Y₃O₄, Si₃N₄, Al₂O₃, the like, or a combination thereof.

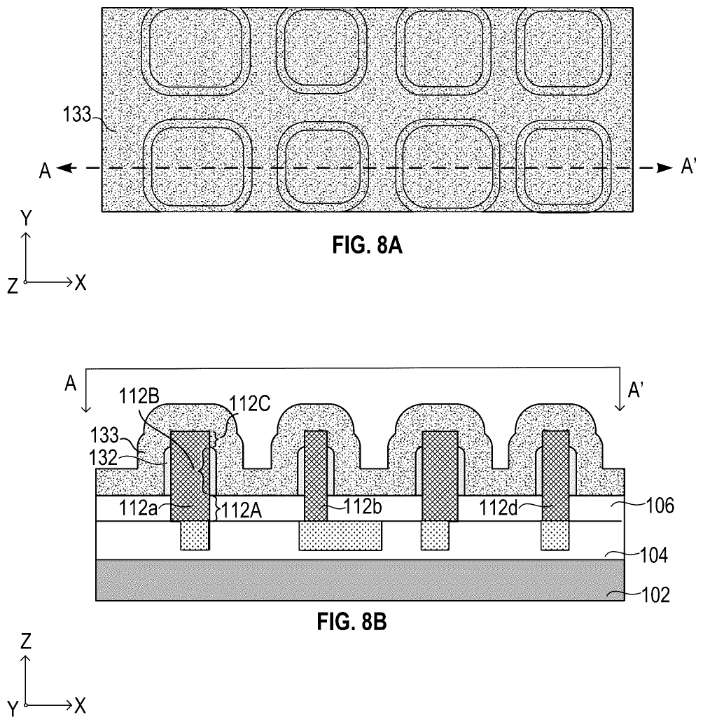

In FIGS. 8A and 8B, the gate dielectric layer 132 can be recessed by a selective etching. Accordingly, portions of the channel structures 112a-112h that are not covered by the gate dielectric layer 132 can become top portions 112C of the channel structures 112a-112h, and portions of the channel structures 112a-112h that are covered by the gate dielectric layer 132 can become middle portions 112B of the channel structures 112a-112h. In some embodiments, the top portions 112C of the channel structures 112a-112h can have a height in a range from 5 nm to 30 nm. Further, a gate electrode stack 133 can be formed over the insulating layer 106, and further cover the gate dielectric layer 132 and the channel structures 112a-112h. The gate electrode stack 133 can include a work function layer (e.g., TiON, TiC, AlTiN, AlTiC, AlTiO), a liner (e.g., TiN and/or TaN), and a filler (e.g., W or Ru).

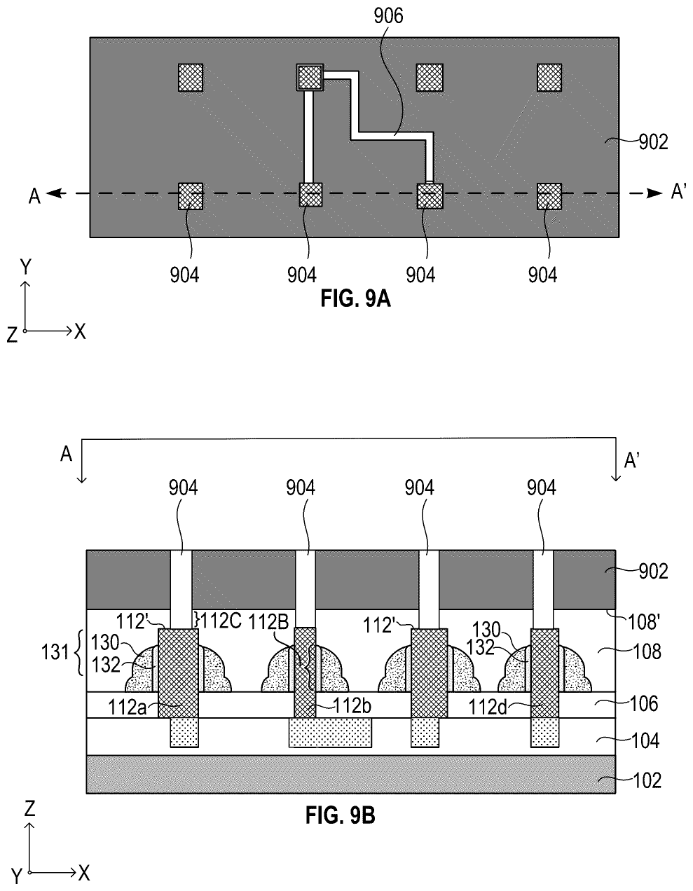

In FIGS. 9A and 9B, the gate electrode stack 133 can be recessed to surround the gate dielectric layer 132 and the middle portions 112B of the channel structures 112a-112h. The remaining gate electrode stack 133 accordingly becomes gate electrodes 130 that are arranged around the middle portions 112B of the channel structures 112a-112h. The gate electrodes 130 and the gate dielectric layers 132 can form gate structures 131. An isolation layer 108 can subsequently be formed to cover the gate structures 131 and the channel structures 112a-112h. It should be noted that a top surface 108′ of the isolation layer 108 is above top surfaces 112′ of the channel structures 112a-112h. A mask layer 902 with patterns can be formed over the isolation layer 108 through a photolithography process, and an etching process can be applied to transfer the patterns of the mask layer 902 into the isolation layer 108 to form a plurality of contact openings 904 and trench openings 906, where the contact openings 904 can be formed to uncover the channel structures 112a-112h.

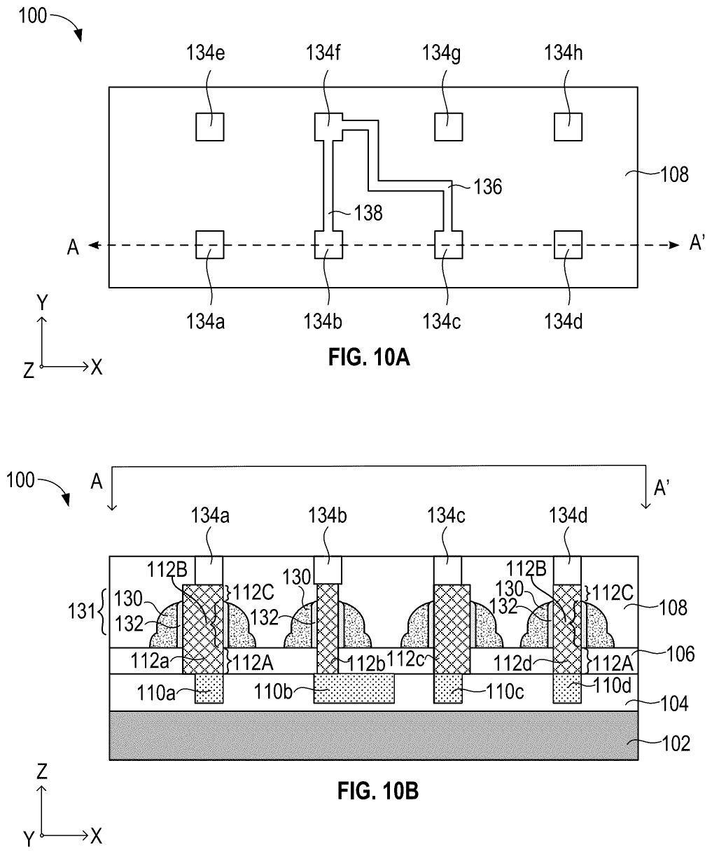

In FIGS. 10A and 10B, the mask layer 902 can be removed, and a conductive material can be deposited into the contact openings 904 and trench openings 906. Any excessive conductive material can be removed by a CMP process or an etching back process. The conductive material that still remains in the contact openings 904 and trench openings 906 can become top contacts 134a-134h and metal lines 136-138. The top contacts 134a-134h can be formed over the channel structures 112a-112h. The metal lines 136-138 can connect two or more of the top contacts 134a-134h to form a functional circuit. When the top contacts 134a-134h and the metal lines 136-138 are formed, a device 100 can accordingly be formed. The device 100 in FIGS. 10A and 10B can have features similar to the device 100 in FIGS. 1A and 1B.

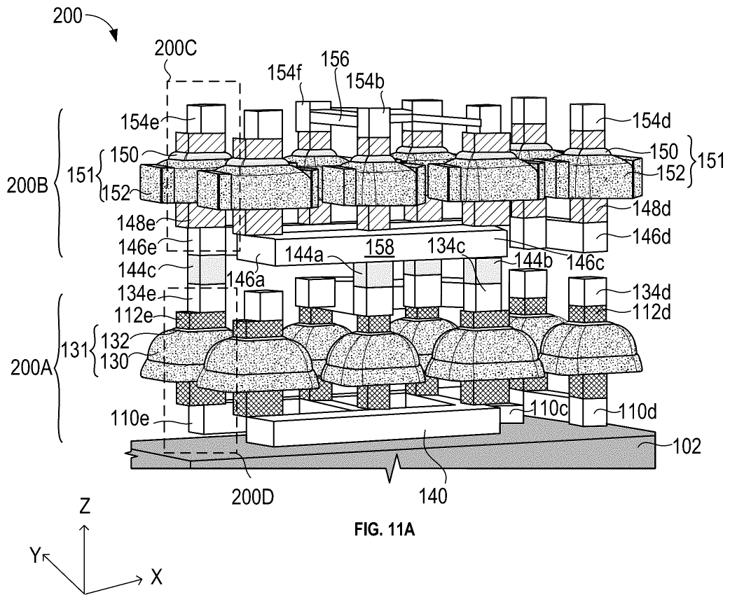

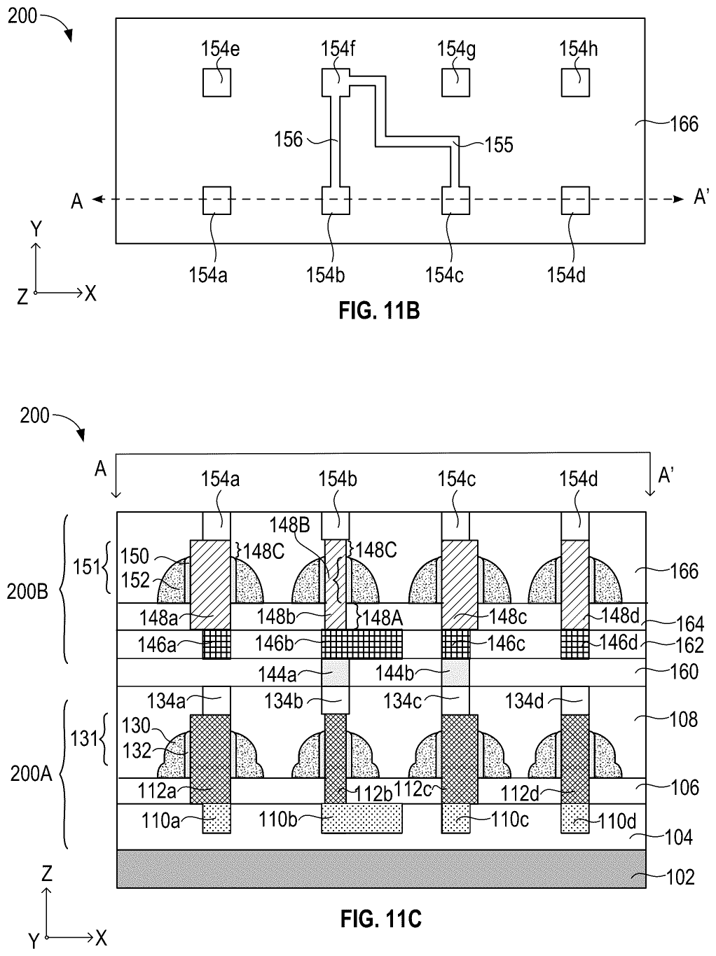

FIG. 11A is a perspective view of a semiconductor device (or device) 200. As shown in FIG. 11A, the device 200 can include a VFET stack. The VFET stack can include a number of VFET layers that are stacked over a substrate 102. For example, a first VFET layer 200A and a second VFET layer 200B are included in FIG. 11A. The first VFET layer 200A can include a plurality of VFETs that are disposed over the substrate 102. The first VFET layer 200A can have features similar to the device 100 shown in FIGS. 1A, 1B, and 1C.

The second VFET layer 200B can also include a plurality of VFETs that are stacked over the VFETs formed in the first VFET layer 200A. As shown in FIG. 11A, the second VFET layer 200B can include a plurality of bottom contacts 146a-146h over the first VFET layer 200A, a plurality of channel structures 148a-148h extending from and in contact with the bottom contacts 146a-146h, a plurality of gate structures 151 around middle portions of the channel structures 148a-148h, and a plurality of top contacts 154e-154h positioned over and in contact with the channel structures 148a-148h. Each of the gate structures 151 can include a gate dielectric layer 150 around a respective channel structure and a gate electrode 152 around the gate dielectric layer 150. Thus, a plurality of VFETs can be formed in the second VFET layer 200B, where each of the VFETs can include a bottom contact, a channel structure, a gate structure, and a top contact. For example, a VFET 200C can be formed in the second VFET layer 200B and a VFET 200D can be formed in the first VFET layer 200A. The VFET 200C can include the bottom contact 146e, the channel structure 148e, the gate structure 151, and the top contact 154e. The VFET 200D can include the bottom contact 110e, the channel structure 112e, the top contact 134e, and the gate structure 131.

Still referring to FIG. 11A, the first VFET layer 200A can be coupled to the second VFET layer 200B through a plurality of interconnect structures 144. For example, the top contact 134c in the first VFET layer 200A can be coupled to the bottom contact 146c in the second VFET layer 200B through an interconnect structure 144b, and the top contact 134e in the first VFET layer 200A can be coupled to the bottom contact 146e in the second VFET layer 200B through an interconnect structure 144c. Accordingly, a plurality of CFET structure can be formed based on the interconnection between the first VFET layer 200A and the second VFET layer 200B. For example, the VFET 200D in the first VFET layer 200A and the VFET 200C in the second VFET layer 200B can be coupled to each other through the interconnect structure 144c, and form a CFET structure.

The second VFET layer 200B can include a plurality of metal lines that can connect the bottom contacts or the top contacts in the second VFET layer 200B. For example, a metal line 158 can be provided to connect the bottom contacts 146a and 146c, and a metal line 156 can be provided to connect the top contacts 154f and 154b. Thus, based on the connection between the bottom contacts and the connections between top contacts, the VFETs in the second VFET layer 200B can be connected to each other so as to form a functional circuit.

In some embodiments, the channel structures 112a-112h in the first VFET layer 200A can be made of a n-type conductive oxide, such as In₂O₃, SnO₂, InGaZnO, and ZnO. The channel structures 148a-148h in the second VFET layer 200B can be made of a p-type conductive oxide, such as SnO. In some embodiments, the channel structures 112a-112h in the first VFET layer 200A can be made of a p-type conductive oxide, and the channel structures 148a-148h in the second VFET layer 200B can be made of a n-type conductive oxide.

FIG. 11B is a top down view of the device 200. As show in FIG. 11B, the top contacts 154a-154h and the meal lines 155-156 of the second VFET layer 200B can be arranged in a dielectric layer 168. The top contact 154b and the top contact 154f can be connected to each other through the metal line 156, and the top contact 154f and the top contact 154c can be connected to each other through the metal line 155.

FIG. 11C is a cross-sectional view of the device 200, which is obtained from a same plane as a vertical plane along line A-A′ in FIG. 11B. As shown in FIG. 11C, the first VFET layer 200A can have features similar to the device 100 shown in FIG. 1B. The interconnect structures 144a-144b can be formed in a dielectric layer 160 that is positioned over the isolation layer 108. The top contact 134b in the first VFET layer 200A can be coupled to the bottom contact 146b in the second VFET layer 200B through the interconnect structure 144a, and top contact 134c in the first VFET layer 200A can be coupled to the bottom contact 146c in the second VFET layer 200B through the interconnect structure 144b. The bottom contacts 146a-146d can be positioned in a dielectric layer 162. The dielectric layer 162 can be positioned over the dielectric layer 160. The channel structures 148a-148d can have bottom portions 148A, middle portions 148B over the bottom portions 148A, and top portions 148C over the middle portions 148B. The bottom portions 148A can be positioned in a dielectric layer 164 that is disposed over the dielectric layer 162. The middle portions 148B and top portions 148C of the channel structures 148a-148d can be arranged in a dielectric layer 166. The dielectric layer 166 can be positioned over the dielectric layer 164. The gate structures 151 can be formed around the middle portions 148B of the channel structures 148a-148d. The top contacts 154a-154d can be formed over the top portions 148C of the channel structures 148a-148d. The top contacts 154a-154d can also be arranged in the dielectric layer 166.

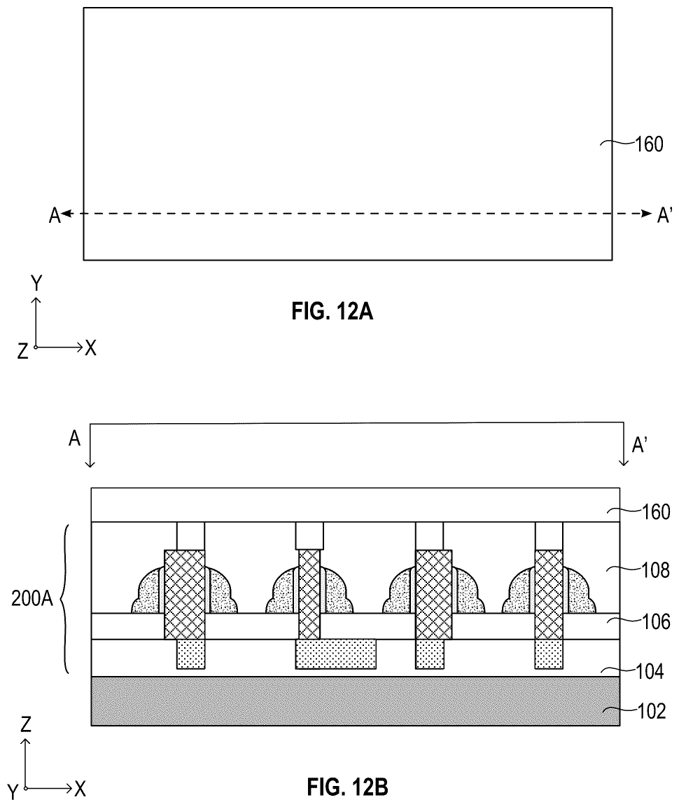

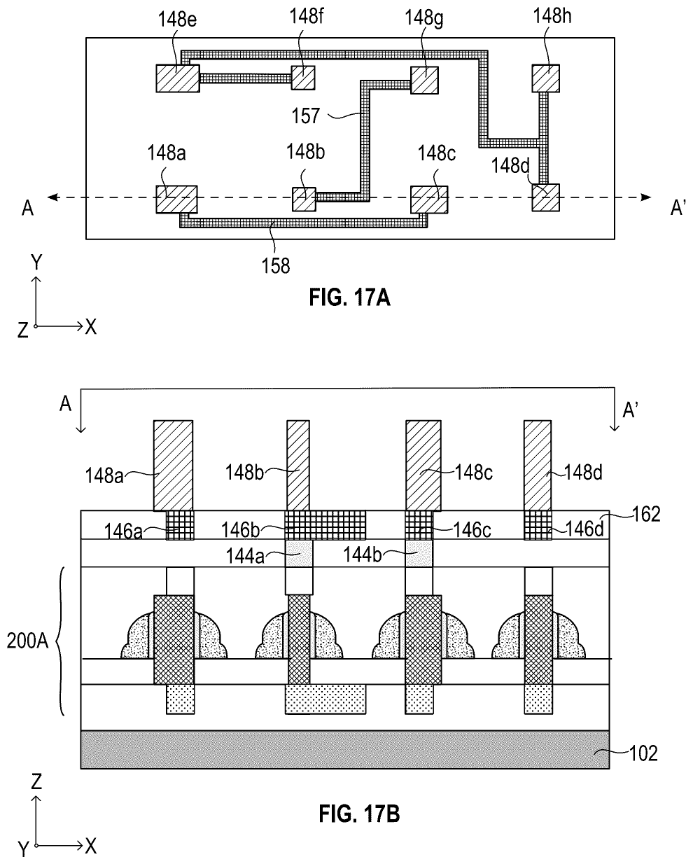

FIGS. 12A, 12B, 13A, 13B, 14A, 14B, 15A, 15B, 16A, 16B, 17A, 17B, 18A, 18B, 19A, 19B, 20A, and 20B are top down views and cross-sectional views of various intermediate steps in a manufacturing flow to fabricate the device 200. As shown in FIGS. 12A and 12B, a first VFET layer 200A can be formed over a substrate 102. Further, a dielectric layer 160 can be formed over the isolation layer 108 of the first VFET layer 200A. The dielectric layer 160 can be made of a dielectric material, such as SiO, SiN, SiON, SiC, SiOC, SiCN, SiOCN, the like, or a combination thereof. The FIG. 12A is a top down view and the FIG. 12B is a cross-sectional view that is obtained from a same plane as a vertical plane along line A-A′ in FIG. 12A.

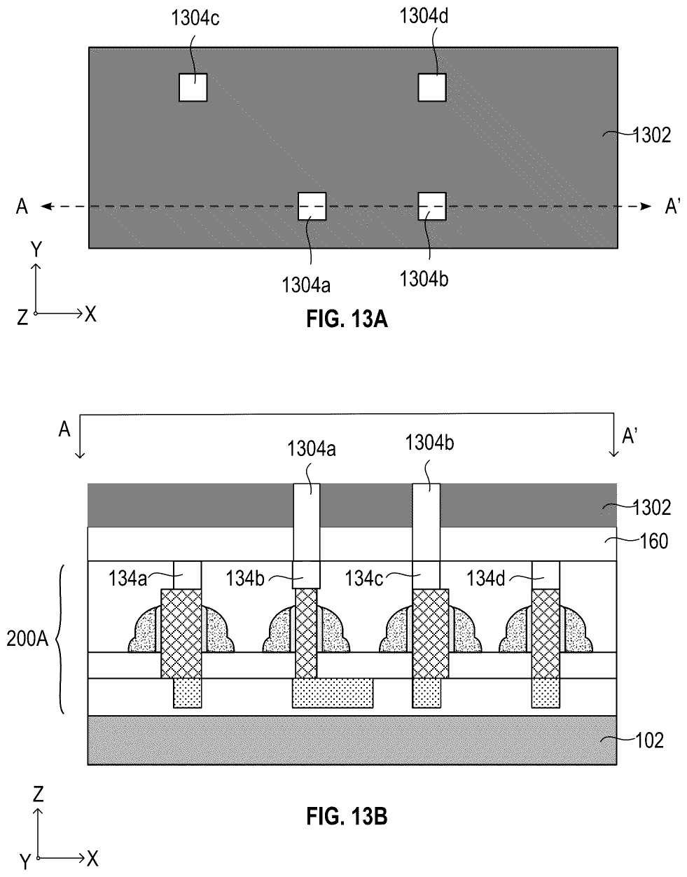

In FIGS. 13A and 13B, a mask layer 1302 with patterns can be formed over the dielectric layer 160 based on a photolithography process. An etching process can subsequently be applied to transfer the patterns into the dielectric layer 160 to form contact openings 1304a-1304d. The contact openings 1304a-1304d can uncover one or more top contacts 134a-134d of the first VFET layer 200A. For example, top contacts 134b and 134c can be uncovered by the contact openings 1304a and 1304b respectively.

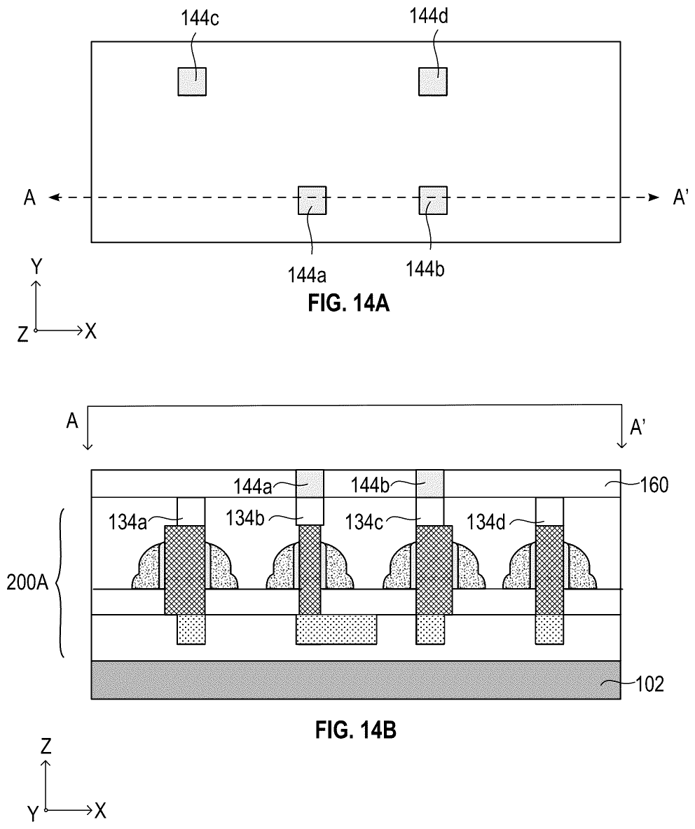

In FIGS. 14A and 14B, a conductive material, such as Co, Ru, W, or the like, can be deposited into the contact openings 1304a-1304d. Any excessive conductive material over the dielectric layer 160 can be removed by a CMP process. The conductive material remaining in the contact openings 1304a-1304d can become interconnect structures. For example, four interconnect structures 144a-144d can be formed over the top contacts 134b, 134c, 134e, and 134g in the first VFET layer 200A.

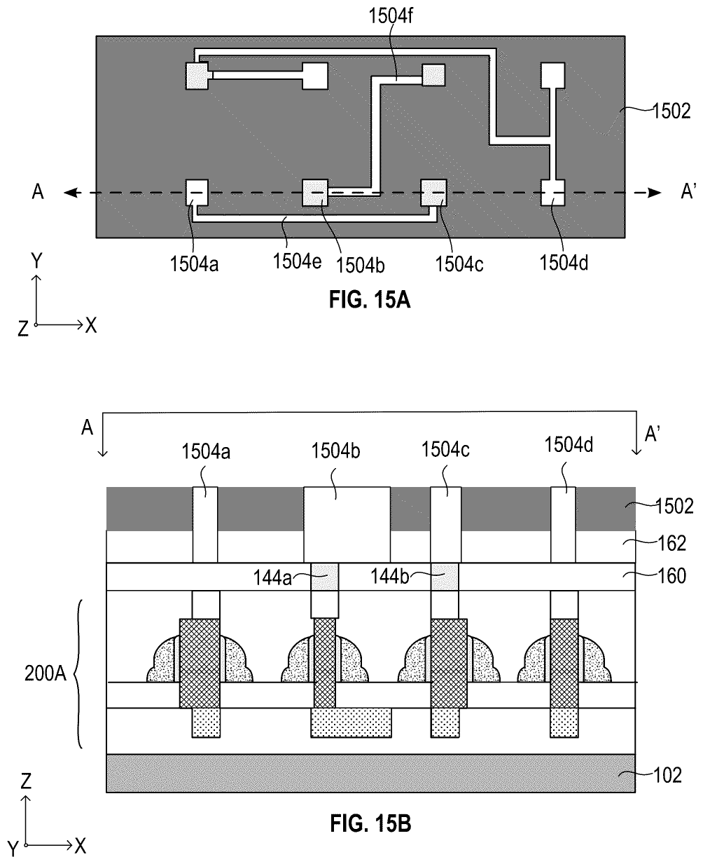

FIG. 15A shows a plurality of contact openings (e.g., 1504a-1504d) and trench openings (e.g., 1504e-1540f) can be formed based on an etching mask 1502. FIG. 15B is a cross-sectional view, which can be obtained from a same plane as a vertical plane along line A-A′ in FIG. 15A. As shown in FIG. 15B, a dielectric layer 162 can be formed over the dielectric layer 160, and the mask 1502 can be formed over the dielectric layer 162. Patterns can be formed in the mask 1502 based on a photolithography process, and an etching process can subsequently transfer the patterns into the dielectric layer 162 to form the contact openings and trench openings. It should be noted that the interconnect structures can be uncovered by the contact openings. For example, the interconnect structure 144a can be uncovered by the contact opening 1504b, and the interconnect structure 144b can be uncovered by the contact opening 1504c.

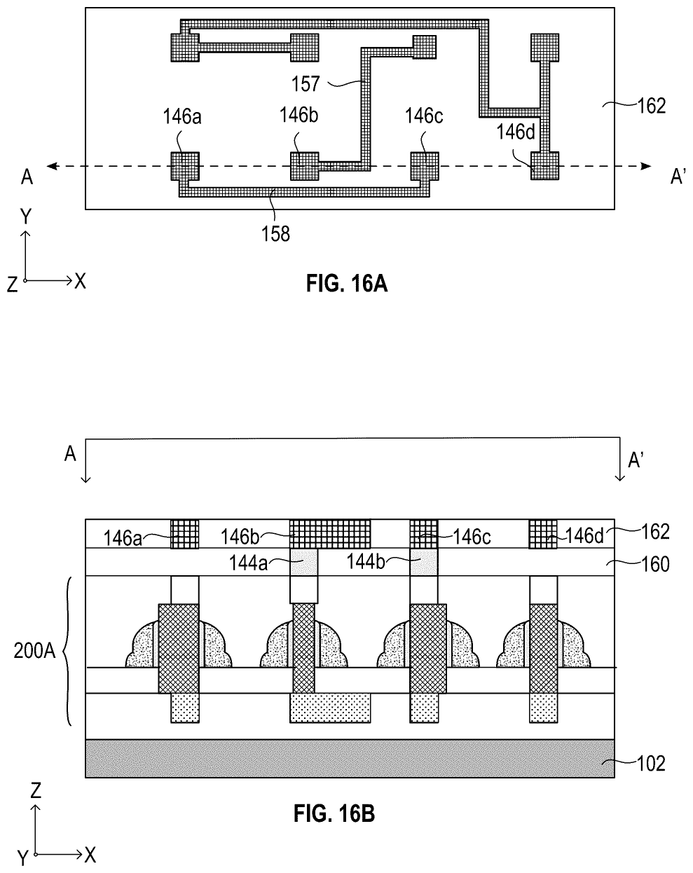

In FIGS. 16A and 16B, a plurality of bottom contacts (e.g., 146a-146d) and metal lines (e.g., 157 and 158) can be formed based on the contact openings and trench openings. FIG. 16A is a top down view and FIG. 16B is a cross-sectional view obtained from a same plane as a vertical plane along line A-A′ in FIG. 16A. In order to form the bottom contacts and metal lines, the mask 1502 can be removed by an etching process or a plasma ashing process. A conductive material, such as W, Co, or Ru, can be deposited into the openings and trench openings. Any excessive conductive material over the dielectric layer 162 can be removed by a CMP process or an etching back process. The conductive material remaining in the openings and the trench openings can become the bottom contacts and metal lines. It should be noted that one or more of the bottom contacts can be in contact with the interconnect structures. For example, the bottom contact 146b is formed over and in contact with the interconnect structure 144a, and the bottom contact 146c is formed over and in contact with the interconnect structure 144b.

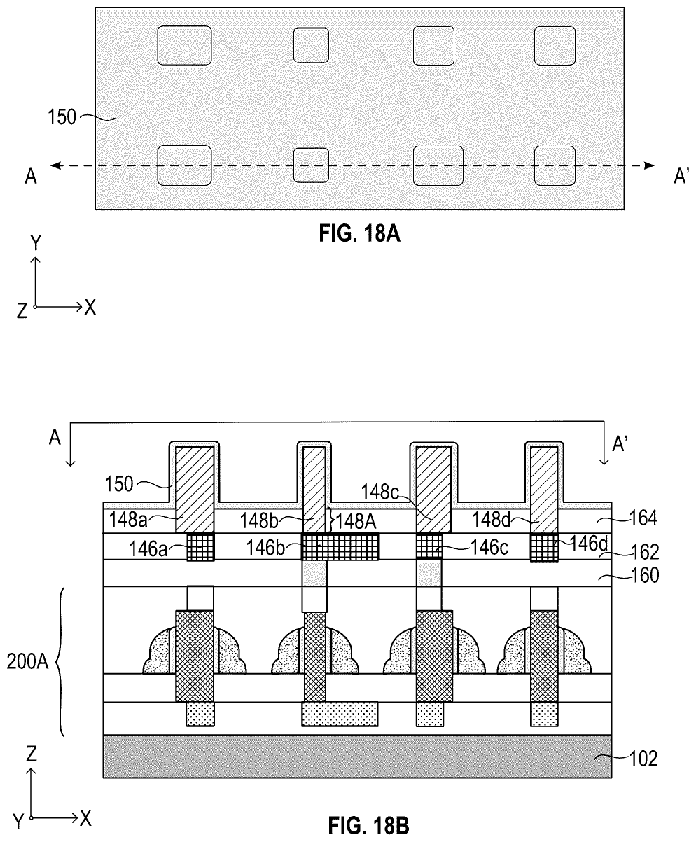

In FIGS. 18A and 18A, a plurality of channel structures 148a-148h can be formed. The channel structures 148a-148h can be aligned with the bottom contacts 146a-146h such that the channel structures 148a-148h can be positioned over and in contact with the bottom contacts 146a-146h. In order to form the channel structures, a conductive oxide layer (not shown) can be formed over the dielectric layer 162. A patterned mask layer (not shown) can be deposited over the conductive oxide layer, and an etching process can be applied to etch the conductive oxide layer based on the patterned mask layer to form the channel structures 148a-148h. The conductive oxide layer can be made of In₂O₃, SnO₂, InGaZnO, ZnO, and SnO.

Still referring to FIGS. 18A and 18B, a dielectric layer 164 can firstly be deposited over the dielectric layer 162 to cover the channel structures 148a-148h. The dielectric layer 164 can further be recessed and bottom portions of the channel structures 148a-148h can still be positioned in the dielectric layer 164. Further, a gate dielectric layer 150 can be formed to cover the channel structures 148a-148h. As shown in FIG. 18B, the gate dielectric layer 150 can be formed over the dielectric layer 164 and positioned on top surfaces and sidewalls of the channel structures 148a-148h conformally.

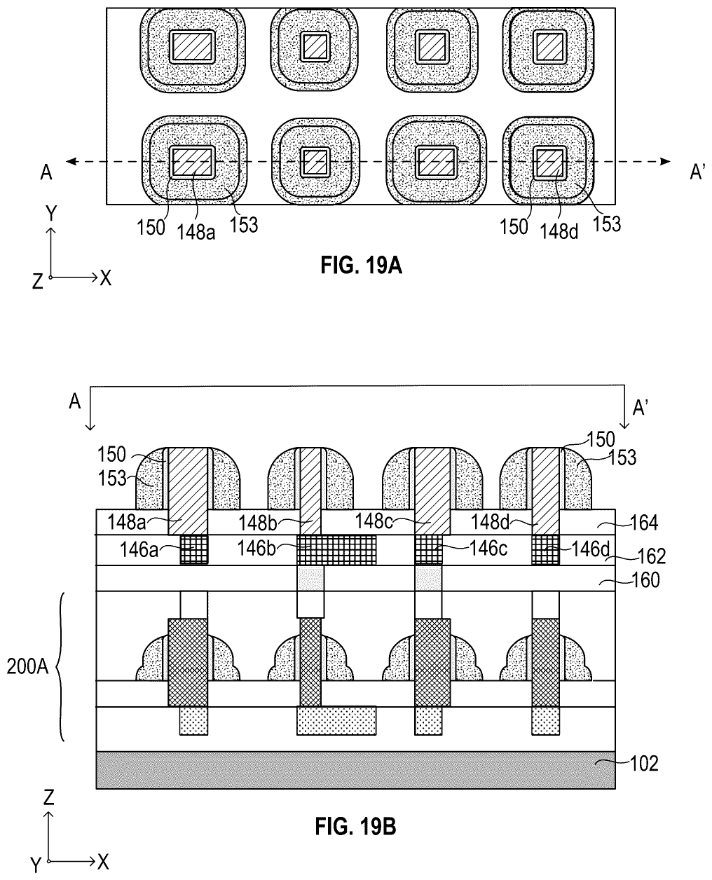

In FIGS. 19A And 19B, an etching process can be applied to remove portions of the gate dielectric layer 150 that are positioned on the top surfaces of the channel structures 148a-148b and over the dielectric layer 164. Portions of the gate dielectric layer 150 positioned over the sidewalls of the channel structures 148a-148b can still remain. Further, gate electrode stacks 153 can be formed around the gate dielectric layer 150. In some embodiments, the gate dielectric layer 150 can include SiO₂, HfO₂, ZrO₂, HfSiNO₂, ZrSiNO₂, Y₃O₄, Si₃N₄, Al₂O₃, the like, or a combination thereof. In some embodiments, the gate electrode stacks 153 can include work function layers (e.g., TiON, TiC, AlTiN, AlTiC, AlTiO), liners (e.g., TiN and/or TaN), and fillers (e.g., W or Ru).

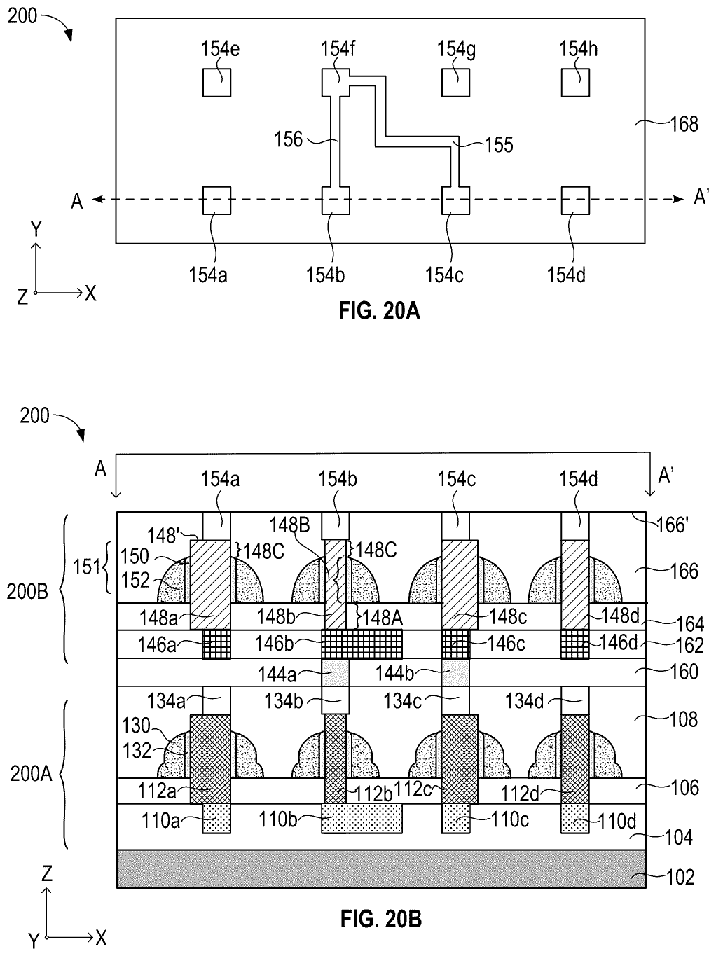

In FIGS. 20A and 20B, the gate electrode stacks 153 and the gate dielectric layers 150 can be recessed. The remaining gate electrode stacks 153 can become gate electrodes 152 that are arranged around the middle portions 148B of the channel structures 148a-148h. The gate electrodes 152 and the gate dielectric layers 150 can accordingly form gate structures 151. A dielectric layer 166 can subsequently be formed to cover the gate structures 151 and the channel structures 148a-148h. It should be noted that a top surface 166′ of the insulating layer 166 is above top surfaces 148′ of the channel structures 148a-148h. Further, a plurality of top contacts 154a-154h can be formed over and in contact with the channel structures 148a-148h. When the top contacts 154a-154h are formed, a device 200 is accordingly formed. The device 200 shown in FIGS. 20A and 20B can have features similar to the device 200 shown in FIGS. 11B and 11C.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a first bottom contact positioned in a dielectric layer over a substrate;
a first channel structure extending from and in contact with the first bottom contact in a vertical direction perpendicular to the substrate, the first channel structure including a bottom portion over the first bottom contact, a middle portion over the bottom portion, and a top portion over the middle portion;
a first gate structure positioned around the middle portion of the first channel structure; and
a first top contact positioned over and in contact with the top portion of the first channel structure.

2. The semiconductor device of claim 1, wherein the first channel structure has one of a circular pillar-shape, a square pillar-shape, an oval pillar-shape, and a rectangular pillar-shape.

3. The semiconductor device of claim 1, wherein:
the bottom portion of the first channel structure has a height in a range from 5 nm to 30 nm,
the top portion of the first channel structure has a height in a range from 5 nm to 30 nm, and
the first channel structure has a height in a range from 15 nm to 90 nm.

4. The semiconductor device of claim 1, wherein the first gate structure further comprises:
a first gate dielectric layer around the middle portion of the first channel structure; and
a first gate electrode around the first gate dielectric layer.

5. The semiconductor device of claim 1, further comprising:
an interconnect structure positioned over the first top contact;
a second bottom contact positioned over the interconnect structure in the vertical direction;
a second channel structure extending from and in contact with the second bottom contact, the second channel structure including a bottom portion over the second bottom contact, a middle portion over the bottom portion, and a top portion over the middle portion;
a second gate structure positioned around the middle portion of the second channel structure; and
a second top contact positioned over and in contact with the top portion of the second channel structure.

6. The semiconductor device of claim 5, wherein the second gate structure further comprises:
a second gate dielectric layer around the middle portion of the second channel structure; and
a second gate electrode around the second gate dielectric layer.

7. The semiconductor device of claim 5, wherein the first channel structure and the second channel structure are made of a conductive oxide that includes one of In₂O₃, SnO₂, InGaZnO, ZnO, and SnO.

8. The semiconductor device of claim 5, wherein the first channel structure is made of a n-type conductive oxide and the second channel structure is made of a p-type conductive oxide.

9. The semiconductor device of claim 5, wherein the first channel structure is made of a p-type conductive oxide and the second channel structure is made of a n-type conductive oxide.

10. The semiconductor device of claim 1, further comprising:
a third bottom contact positioned in the dielectric layer over the substrate;
a third channel structure extending from and in contact with the third bottom contact in the vertical direction, the third channel structure including a bottom portion over the third bottom contact, a middle portion over the bottom portion, and a top portion over the middle portion;
a third gate structure positioned around the middle portion of the third channel structure; and
a third top contact positioned over and in contact with the top portion of the third channel structure, wherein
the third channel structure and the first channel structure are arranged side by side over the substrate in a horizontal direction parallel to the substrate, and
the first top contact and the third top contact are coupled to each other through a metal layer that is parallel to a main surface of the substrate.

11. A method of forming a semiconductor device, comprising:
forming a first bottom contact in a dielectric layer over a substrate;
forming a first channel structure extending from and in contact with the first bottom contact in a vertical direction perpendicular to the substrate, the first channel structure including a bottom portion over the first bottom contact, a middle portion over the bottom portion, and a top portion over the middle portion;
forming a first gate structure around the middle portion of the first channel structure; and
forming a first top contact over and in contact with the top portion of the first channel structure.

12. The method of claim 11, wherein the forming the first channel structure further comprises:
forming an insulating layer over the dielectric layer;
forming an opening in the insulating layer to uncover the first bottom contact; and
depositing a conduct oxide in the opening to form the first channel structure.

13. The method of claim 12, wherein the forming the first gate structure further comprises:
recessing the insulating layer such that the middle portion and the top portion of the first channel structure are uncovered;
forming a first gate dielectric layer around the middle portion and the top portion of the first channel structure;
forming a first gate electrode around the first gate dielectric layer; and
recessing the first gate dielectric layer and the first gate electrode such that the top portion of the first channel structure is uncovered.

14. The method of claim 13, wherein the forming the first top contact further comprises:
forming an isolation layer over the insulating layer such that a top surface of the isolation layer is above a top surface of the first channel structure;
forming an opening in the isolation layer to uncover the top surface of the first channel structure; and
depositing a conductive material in the opening to form the first top contact.

15. The method of claim 14, further comprising:
forming an interconnect structure over the first top contact;
forming a second bottom contact over the interconnect structure;
forming a second channel structure extending from and in contact with the second bottom contact in the vertical direction, the second channel structure including a bottom portion over the second bottom contact, a middle portion over the bottom portion, and a top portion over the middle portion;
forming a second gate structure around the middle portion of the second channel structure; and
forming a second top contact over and in contact with the top portion of the second channel structure.

16. The method of claim 15, wherein the forming the second gate structure further comprises:
forming a second gate dielectric layer around the middle portion of the second channel structure; and
forming a second gate electrode around the second gate dielectric layer.

17. The method of claim 11, further comprising:
forming a third bottom contact in the dielectric layer;
forming a third channel structure extending from and in contact with the third bottom contact in the vertical direction, the third channel structure including a bottom portion over the third bottom contact, a middle portion over the bottom portion, and a top portion over the middle portion;
forming a third gate structure around the middle portion of the third channel structure; and
forming a third top contact over and in contact with the top portion of the third channel structure, wherein
the third channel structure and the first channel structure are arranged side by side over the substrate in a horizontal direction parallel to the substrate, and
the first top contact and the third top contact are coupled to each other through a metal layer that is parallel to a main surface of the substrate.

18. The method of claim 15, wherein the first channel structure and the second channel structure are made of a conductive oxide that includes one of In₂O₃, SnO₂, InGaZnO, ZnO, and SnO.

19. The method of claim 15, wherein:
the first channel structure and the second channel structure include one of a n-type conductive oxide and a p-type conductive oxide.

20. The method of claim 11, wherein:
the bottom portion of the first channel structure has a height in a range from 5 nm to 30 nm,
the top portion of the first channel structure has a height in a range from 5 nm to 30 nm, and
the first channel structure has a height in a range from 15 nm to 90 nm.
